(19) United States
(12) Patent Application Publication
(10) Pub. No.: US 2025/0046753 A1
(43) Pub. Date: Feb. 6, 2025

(54) INTEGRATED CIRCUIT PACKAGE AND METHOD

(71) Applicant: Taiwan Semiconductor Manufacturing Co., Ltd., Hsinchu (TW)

(72) Inventors: Chih-Wei Wu, Zhuangwei Township (TW); Ying-Ching Shih, Hsinchu (TW)

(21) Appl. No.: 18/363,096

(22) Filed: Aug. 1, 2023

(51) Int. Cl. H01L 25/065; H01L 21/56; H01L 21/78; H01L 23/00; H01L 23/31; H01L 25/00

(52) U.S. Cl. CPC H01L 25/0652; H01L 21/561; H01L 21/78; H01L 23/3185; H01L 23/3192; H01L 24/05; H01L 24/08; H01L 24/13; H01L 24/16; H01L 24/80; H01L 24/81; H01L 24/94; H01L 24/97; H01L 25/50; H01L 23/291; H01L 23/296; H01L 24/32; H01L 24/73; H01L 24/83; H01L 24/92; H01L 2224/05647; H01L 2224/13025; H01L 2224/13111; H01L 2224/13124; H01L 2224/13139; H01L 2224/13144; H01L 2224/13147; H01L 2224/13155; H01L 2224/13164; H01L 2224/16227; H01L 2224/32225; H01L 2224/73204; H01L 2224/8001; H01L 2224/80357; H01L 2224/80379; H01L 2224/80896; H01L 2224/81815; H01L 2224/83102; H01L 2224/92125; H01L 2224/94; H01L 2224/97; H01L 2924/0504; H01L 2924/0544; H01L 2924/059; H01L 2924/10156; H01L 2924/1816; H01L 2924/186

(57) ABSTRACT

A method of manufacturing a semiconductor device, the method includes bonding a first die and a second die to a first side of a wafer, wherein after bonding the first die and the second die to the first side of the wafer, a gap is disposed between the first die and the second die, wherein a first portion of the gap has a first width that is larger than a second width of a second portion of the gap, depositing a third dielectric layer on top surfaces and sidewalls of the first die and the second die, as well as on a bottom surface within the gap, forming a molding material over the third dielectric layer to fill the gap, and performing a planarization process to expose top surfaces of the first die and the second die.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 3 illustrate cross-sectional views of intermediate steps during a process for forming semiconductor dies in accordance with some embodiments.

FIGS. 4 through 12 illustrate cross-sectional views of intermediate steps during a process for forming an integrated chip package in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to forming a 3D integrated chip (3DIC) package, such as a system on integrated chip (SoIC) package. Forming the integrated chip package comprises bonding two or more semiconductor dies (e.g., top dies) to a semiconductor wafer (e.g., a bottom die). A dielectric layer (e.g., an oxide) is formed on top surfaces and sidewalls of the semiconductor dies, and on bottom surfaces of gaps between the semiconductor dies. A molding compound is then formed to fill the remainder of the gaps. Advantageous features of one or more embodiments disclosed herein may include better bonding strength of the dielectric layer as compared to the molding compound, allowing improved bonding of the semiconductor dies to the semiconductor wafer. In addition, the dielectric layer has a lower thermal expansion than the molding compound during a thermal process that is used to cure the molding compound. As a result, each semiconductor die has a better bending resistance at each die corner, and a risk of delamination of the semiconductor die is reduced. This further results in a more robust integrated chip package, with better electrical connection to any external devices (e.g., a package substrate), which allows for an enhancement in device reliability.

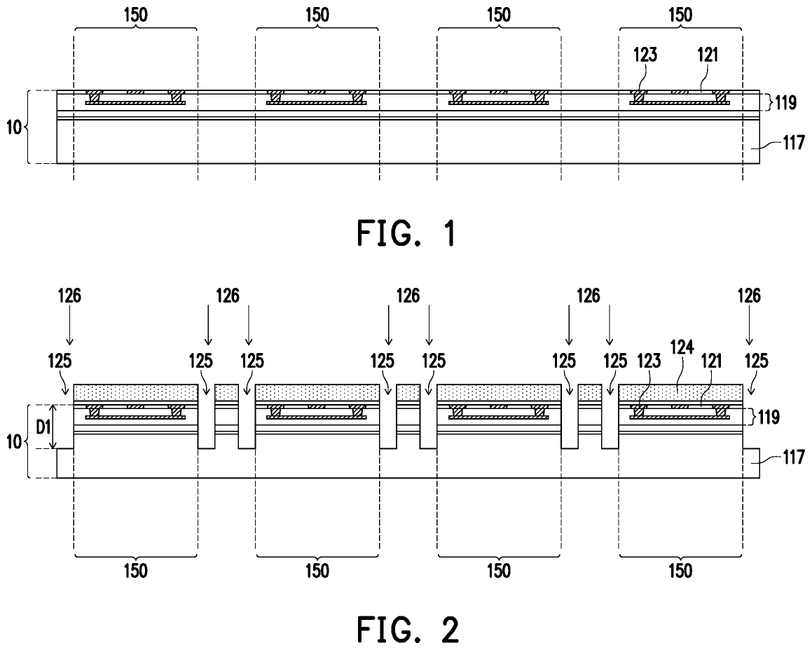

FIGS. 1 through 12 illustrate cross-sectional views of intermediate steps during a process for forming an integrated chip package 100, in accordance with some embodiments. In FIG. 1, a wafer 10 is illustrated. The wafer 10 comprises semiconductor dies 150. Each of the semiconductor dies 150 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wideIO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each semiconductor die 150 may also be a System-on-Chip (SoC) die, or the like. The wafer 10 may include a substrate 117 (e.g., a semiconductor substrate), an interconnect structure 119 disposed on the substrate 117, a bonding layer 121 disposed on the interconnect structure 119, and bonding pads 123 disposed in the bonding layer 121 and exposed at the front surface of the wafer 10. The side of the wafer 10 comprising the exposed bonding pads 123 and the bonding layer 121 may also be referred to subsequently as the front side of the wafer 10.

The substrate 117 of the wafer 10 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the substrate 117. The devices may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide (SiOₓ, where x>0), silicon nitride (SiNₓ, where x>0), silicon oxynitride (SiOₓN_{y}, where x>0 and y>0), or other suitable dielectric material. The interconnect wirings may include metallic wirings. For example, the interconnect wirings include copper wirings, copper pads, aluminum pads or combinations thereof that are formed by one or more single damascene processes, dual damascene processes, or the like. The side of the wafer 10 comprising an exposed back side surface of the substrate 117 may also be referred to subsequently as the back side of the wafer 10.

The bonding layer 121 may comprise a dielectric layer. Bonding pads 123 are embedded in the bonding layer 121, and the bonding pads 123 allow connections to be made to the interconnect structure 119 and the devices on the substrate 117. The material of the bonding layer 121 may be silicon oxide (SiOₓ, where x>0), silicon nitride (SiNₓ, where x>0), silicon oxynitride (SiOₓN_{y}, where x>0 and y>0), tetraethyl orthosilicate (TEOS), or other suitable dielectric material, and the bonding pads 123 may comprise conductive pads (e.g., copper pads), conductive vias (e.g., copper vias), or combinations thereof. The bonding layer 121 may be formed by depositing a dielectric material over the interconnect structure 119 using a chemical vapor deposition (CVD) process (e.g., a plasma enhanced CVD process or other suitable process); patterning the dielectric material to form the bonding layer 121 including openings or through holes; and filling conductive material in the openings or through holes defined in the bonding layer 121 to form the bonding pads 123 embedded in the bonding layer 121.

In FIG. 2, a mask layer 124 (e.g., a photoresist) is formed over the wafer 10, such as over the bonding layer 121 and the bonding pads 123. The mask layer 124 is patterned using suitable development and exposure techniques to form openings in the mask layer that expose top surfaces of the wafer 10. A plasma dicing process 126 is then performed to form grooves 125 that extend partially through the exposed portions of the wafer 10. In an embodiment, the plasma dicing process 126 is a dry etch process that comprises a fluorine plasma, or the like that can be used to etch narrow, deep vertical trenches. In an embodiment, the plasma dicing process 126 may be a dry plasma process, such as a deep reactive ion etching (DRIE) process using plasma gases that comprise sulphur hexafluoride (SF₆), Octafluorocyclobutane (C₄F₈), or the like. As a result of the plasma dicing process 126, a first groove 125 and a second groove 125 is disposed between adjacent sidewalls of pairs of the semiconductor dies 150. Each groove 125 may have a depth Di that is in a range from 10 μm to 700 μm. In some embodiments, each groove 125 may extend through the bonding layer 121, the interconnect structure 119, and partially through the substrate 117.

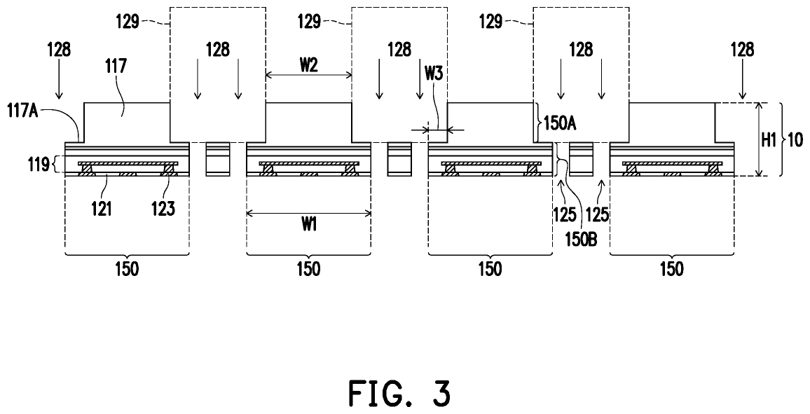

In FIG. 3, the mask layer 124 is removed using an acceptable ashing or stripping process. A temporary adhesive tape, (e.g., back grinding tape), may then be applied to the front side of the wafer 10, such as over the bonding layer 121, the bonding pads 123, and the interconnect structure 119. The wafer 10 is then flipped over, and a thinning process may then be performed on the back side of the wafer 10. The thinning process may be performed, e.g., using mechanical grinding or chemical mechanical polishing (CMP) processes whereby chemical etchants and abrasives are utilized to react and grind away portions of the substrate 117. The back grinding tape is used to provide mechanical support during this thinning process. After the thinning process, the back grinding tape may then be removed using a suitable process. In an embodiment, after the thinning process, a height H1 of the wafer 10 may be in a range from 100 μm to 700 μm. In another embodiment, the height H1 of the wafer 10 may be larger than 350 μm.

After the thinning process described above, the wafer 10 is then mounted to a tape (not shown in the FIG. 3) supported by a frame (not shown in the FIG. 3). For example, the front side of the wafer 10 (e.g., the bonding layer 121 and the bonding pads 123) is attached to the tape (not shown in the FIG. 3) supported by the frame (not shown in the FIG. 3). The tape may be a dicing tape for holding the wafer 10 in place during subsequent processing.

A blade dicing process 128 is then performed along dicing paths 129 (indicated by the dashed lines in FIG. 3). Each dicing path 129 is disposed between adjacent semiconductor dies 150. In addition, each dicing path 129 also overlaps the two adjacent grooves 125 between the adjacent semiconductor dies 150. Further, the dicing path 129 may also encompass edge portions of each of the adjacent semiconductor dies 150. The blade dicing process 128 forms trenches along the dicing paths 129 that extend partially through the substrate 117 and connect to the grooves 125, which results in the singulation of the semiconductor dies 150 from each other along the dicing paths 129. The blade dicing process 128 comprises using an abrasive disc or blade saw rotating at high speed to cut along the dicing path 129. The blade tip may comprise abrasive grit or a thin diamond layer.

Each singulated semiconductor die 150 comprises a top portion of the semiconductor die 150A and a bottom portion of the semiconductor die 150B. The bottom portion of the semiconductor die 150B may have a larger width W1 than a width W2 of the top portion of the semiconductor die 150A. In this way, each sidewall of the bottom portion of the semiconductor die 150B is offset from a respective sidewall of the top portion of the semiconductor die 150A by a width W3. Each of the semiconductor dies 150 may have stepped surfaces 117A, which also define top surfaces of the bottom portion of the semiconductor die 150B. Each stepped surface 117A may have the width W3. In an embodiment, the stepped surfaces 117A may be rounded or be a curved surface. A cleaning process or rinse may then be performed to clean surfaces of the semiconductor dies 150. In an embodiment, the cleaning process may comprise exposing the surfaces of the semiconductor dies 150 to a cleaning solution, de-ionized water, or the like.

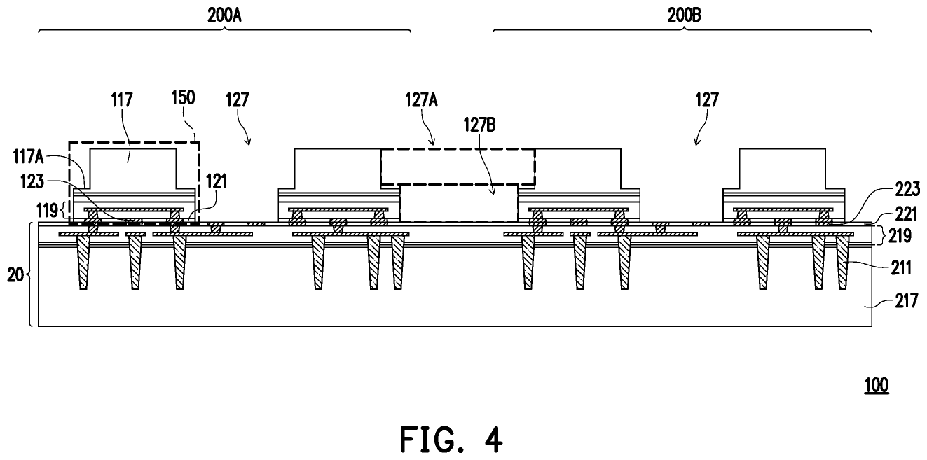

In FIG. 4, a semiconductor wafer 20 is bonded to the semiconductor dies 150. The wafer 20 may also be subsequently referred to as a bottom die. The wafer 20 comprises a first package region 200A and a second package region 200B, and one or more of the integrated chip package 100 are packaged to form an integrated circuit package in each of the package regions 200A and 200B. The materials and formation processes of the features in the wafer 20 may be found by referring to the like features in the wafer 10, with the like features in the wafer 10 starting with number “1,” which features correspond to the features in the wafer 20 and having reference numerals starting with number “2.” For example, the wafer 20 may include a substrate 217 having devices (e.g., transistors, capacitors, diodes, resistors, or the like) formed thereon and an interconnect structure 219. The interconnect structure 219 electrically connects the devices on the substrate 217 to form one or more integrated circuits. The interconnect structure 219 includes one or more dielectric layers (for example, one or more interlayer dielectric (ILD) layers, intermetal dielectric (IMD) layers, or the like) and interconnect wirings or metallization patterns embedded in the one or more dielectric layers.

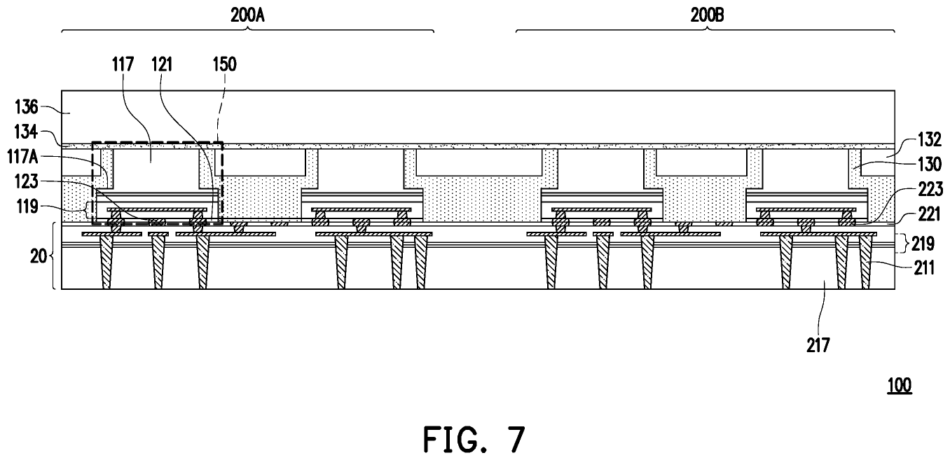

A bonding layer 221 is disposed on the interconnect structure 219, and bonding pads 223 are disposed in the bonding layer 221. The bonding pads 223 allow connections to be made to the interconnect structure 219 and the devices on the substrate 217. The wafer 20 further includes through substrate vias (TSVs) 211 which may be electrically connected to the metallization patterns in the interconnect structure 219. The TSVs 211 may be formed by forming recesses in the substrate 217 by, for example, etching, milling, laser techniques, a combination thereof, and/or the like. A thin barrier layer may be conformally deposited over the front side of the substrate 217 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 217 by, for example, chemical mechanical polishing. Thus, in some embodiments, the TSVs 211 may comprise a conductive material and a thin barrier layer between the conductive material and the substrate 217. In subsequent processing steps, the substrate 217 may be thinned to expose the TSVs 211 (see FIG. 7). After thinning, the TSVs 211 provide electrical connection from a back side of the substrate 217 to a front side of the substrate 217. In various embodiments, the back side of the substrate 217 may refer to a side of the substrate 217 opposite to the devices and the interconnect structure 219 while the front side of the substrate 217 may refer to a side of the substrate 217 on which the devices and the interconnect structure 219 are disposed.

Still referring to FIG. 4, the semiconductor dies 150 are bonded to the wafer 20, for example, in a hybrid bonding configuration. The semiconductor dies 150 are disposed face down such that front sides of the semiconductor dies 150 face the wafer 20 and back sides of the semiconductor dies 150 face away from the wafer 20. The semiconductor dies 150 are bonded to the bonding layer 221 on the front side of the wafer 20 and the bonding pads 223 in the bonding layer 221. For example, the bonding layer 121 of the semiconductor dies 150 may be directly bonded to the bonding layer 221 of the wafer 20, and bonding pads 123 of the semiconductor dies 150 may be directly bonded to the bonding pads 223 of the wafer 20. In an embodiment, the bond between the bonding layer 121 and the bonding layer 221 may be an oxide-to-oxide bond, or the like. The hybrid bonding process further directly bonds the bonding pads 123 of the semiconductor dies 150 to the bonding pads 223 of the wafer 20 through direct metal-to-metal bonding. Thus, electrical connection between the semiconductor dies 150 and the wafer 20 is provided by the physical connection of the bonding pads 123 to the bonding pads 223.

As an example hybrid bonding process starts with aligning the semiconductor dies 150 with the wafer 20, for example, by applying a surface treatment to one or more of the bonding layer 121 or the bonding layer 221. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the bonding layer 221. The hybrid bonding process may then proceed to aligning the bonding pads 123 to the bonding pads 223. Next, the hybrid bonding includes a pre-bonding step, during which the semiconductor dies 150 are put in contact with the wafer 20. The pre-bonding may be performed at room temperature (e.g., between about 21° C. and about 25° C.). The hybrid bonding process continues with performing an anneal, for example, at a temperature between about 150° C. and about 400° C. for a duration between about 0.5 hours and about 3 hours, so that the metal in bonding pads 123 (e.g., copper) and the metal of the bonding pads 223 (e.g., copper) inter-diffuses to each other, and hence the direct metal-to-metal bonding is formed. Although four semiconductor dies 150 are illustrated as being bonded to the wafer 20, other embodiments may include any number of semiconductor dies 150 bonded to the wafer 20. After bonding the semiconductor dies 150 to the wafer 20, gaps 127 may be disposed between sidewalls of adjacent semiconductor dies 150. For example a lower portion of each gap 127B may be disposed between sidewalls of adjacent bottom portions of the semiconductor dies 150B, while an upper portion of each gap 127A may be disposed between sidewalls of adjacent top portions of the semiconductor dies 150A. The upper portion of the gap 127A may have a larger width than the lower portion of the gap 127B.

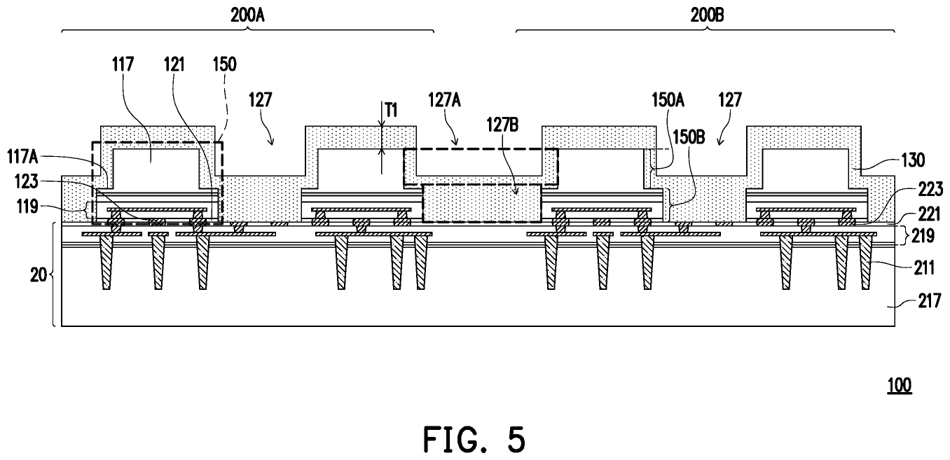

In FIG. 5, a dielectric layer 130 is formed over the structure shown in FIG. 4 and within the gaps 127. For example, the dielectric layer 130 is formed on top surfaces and sidewalls of the semiconductor dies 150. In an embodiment, the dielectric layer 130 is formed over a top surface and sidewalls of a top portion of each semiconductor die 150A. The dielectric layer 130 is also formed on top surfaces (e.g., stepped surfaces 117A) and sidewalls of a bottom portion of each semiconductor die 150B. In addition, the dielectric layer 130 is formed on bottom surfaces within the gaps 127, such that the dielectric layer 130 is in physical contact with top surfaces of the wafer 20. The dielectric layer 130 may be deposited conformally using a process such as chemical vapor deposition (CVD), atomic layer deposition (ALD), or the like. In an embodiment, the dielectric layer may comprise silicon oxide (SiOₓ, where x>0), silicon nitride (SiNₓ, where x>0), silicon oxynitride (SiOₓN_{y}, where x>0 and y>0), or the like. In other embodiments, the dielectric layer 130 may comprise silicon carbon nitride (SiCN), tetraethyl orthosilicate (TEOS), undoped silicate glass (USG), or the like. In other embodiments, the dielectric layer 130 may be a highly conformal and dense dielectric film formed using a high-density plasma (HDP) deposition method such as plasma enhanced chemical vapor deposition (PECVD), or the like. In an embodiment, a thickness T1 of the dielectric layer 130 may be in a range from 0.1 μm to 2 μm. Because the lower portion of the gap 127B has a smaller width than the upper portion of the gap 127A, the dielectric layer 130 may completely fill the lower portion of each gap 127B, and only partially fill the upper portion of each gap 127A. In an embodiment, the dielectric layer 130 may have a co-efficient of thermal expansion that is in a range from 0.1 μm/m·° C. to 5 μm/m·° C.

Advantages can be achieved by forming the dielectric layer 130 on the top surfaces and sidewalls of the semiconductor dies 150, as well as within the gaps 127, with the dielectric layer 130 having the thickness T1 that is in a range from 0.1 μm to 2 μm. These advantages include the dielectric layer 130 having high bonding strength which results in improved bonding of the semiconductor dies 150 to the semiconductor wafer 20. As a result, each semiconductor die 150 has a better bending resistance at each die corner, and a risk of delamination of the semiconductor die 150 is reduced. For example, the dielectric layer 130 having a thickness that is lower than 0.1 μm would result in an insufficient bonding strength between the semiconductor dies 150 and the semiconductor wafer 20, resulting in an increased risk of delamination of the semiconductor dies 150. Additional advantages may be achieved by forming the dielectric layer 130 over the stepped surfaces 117A of the semiconductor dies 150. These include allowing for more dielectric material to be deposited on each semiconductor die 150 as a result of the increased surface area available due to the step structure of the stepped surfaces 117A. This allows for even better bonding strength and improves the bonding between the semiconductor dies 150 to the semiconductor wafer 20.

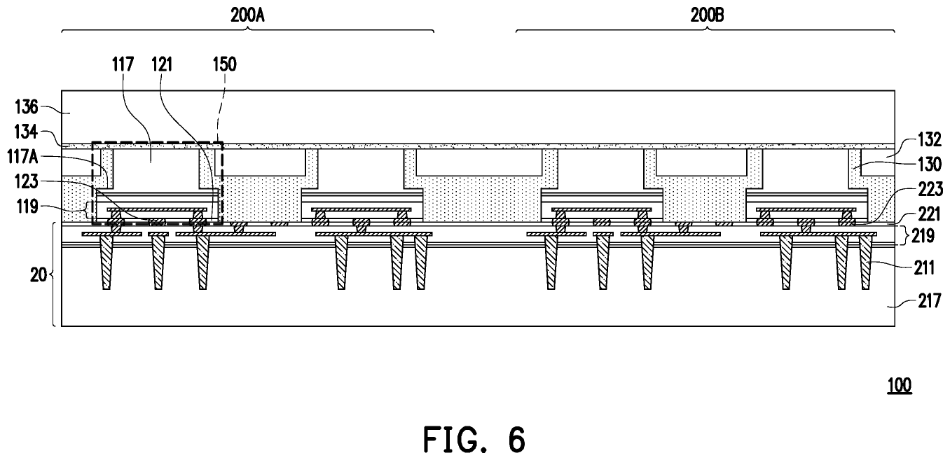

In FIG. 6, a molding material (or molding compound) 132 is formed over the structure shown in FIG. 5 in order to fill the gaps 127. For example, the molding material 132 maybe formed on surfaces of the dielectric layer 130, and within the gaps 127 in order to fill the upper portion of each gap 127A. The molding material 132 is isolated from top surfaces of the wafer 20, and from sidewalls and top surfaces of the semiconductor dies 150 by the dielectric layer 130. The molding material 132 can comprise a dielectric material, such as silicon-based material, an epoxy molding compound that includes silica, or the like. The molding material 132 may be formed using any suitable process, such as, spin-coating, a deposition process, an injection process, or the like. After the formation of the molding material 132, a curing process may be performed at a temperature in a range from 100° C. to 250° C., in order to harden the molding material 132. In an embodiment, the molding material is disposed above the bottom portions of the semiconductor dies 150B. In an embodiment, the molding material 132 may have a co-efficient of thermal expansion that is in a range from 5 μm/m·° C. to 50 μm/m·° C. In an embodiment, the co-efficient of thermal expansion of the dielectric layer 130 may be lower than the co-efficient of thermal expansion of the molding material 132.

Advantages can be achieved by forming the dielectric layer 130 and the molding material 132 within the gaps 127, such that the dielectric layer 130 is disposed between the sidewalls of the semiconductor dies 150 and the molding material 132, and between the wafer 20 and the molding material 132, wherein the dielectric layer 130 has the thickness Ti that is in a range from 0.1 μm to 2 μm. These advantages include the dielectric layer 130 having a lower co-efficient of thermal expansion than the molding material 132, the co-efficient of thermal expansion of the dielectric layer 130 being in a range from 0.1 μm/m·° C. to 5 μm/m·° C., such that during the curing process described above that is used to cure the molding material 132, the dielectric layer 130 undergoes a smaller amount of thermal expansion. As a result, each semiconductor die 150 has a better bending resistance at each die corner, and a risk of delamination of the semiconductor die 150 is reduced. For example, the dielectric layer 130 having a thickness that is lower than 0.1 μm would allow the molding material to be excessively close to the die corners of the semiconductor dies 150, and the thermal expansion of this molding material 132 would result in an increased risk of delamination of the semiconductor dies 150. Therefore, forming the dielectric layer 130 and the molding material 132 within the gaps 127 as described above, wherein the dielectric layer 130 has the thickness T1 that is in a range from 0.1 μm to 2 μm, results in a more robust integrated chip package 100, with better electrical connection to any external devices (e.g., a package substrate), which allows for an enhancement in device reliability.

After the formation of the molding material 132, a planarization process is performed to remove excess portions of the molding material 132. In addition, during the planarization process, portions of the dielectric layer 130 are also removed to expose top surfaces of the semiconductor dies 150. The planarization process may comprise a grinding process, a CMP process, or the like. As illustrated in FIG. 6, the planarization process may result in top surfaces of the semiconductor dies 150 and the dielectric layer 130, being level with top surfaces of the molding material 132.

After the planarization process, a carrier substrate 136 is attached to the planarized surfaces of the semiconductor dies 150, the dielectric layer 130, and the molding material 132. In an embodiment the carrier substrate 136 comprises, for example, silicon based materials, such as glass or silicon oxide, or other materials, such as aluminum oxide, combinations of any of these materials, or the like. The carrier substrate 136 is planar in order to accommodate the attachment of the semiconductor dies 150, the dielectric layer 130, and the molding material 132, which may be attached using a release layer 134. The release layer 134 may be formed of a polymer-based material, which may be removed along with the carrier substrate 136 from the underlying structures in subsequent steps. In some embodiments, the release layer 134 is an epoxy-based thermal-release material, which loses its adhesive property when heated, such as a light-to-heat-conversion (LTHC) release coating. In other embodiments, the release layer 134 may be an ultra-violet (UV) glue, which loses its adhesive property when exposed to UV lights. The release layer 134 may be dispensed as a liquid and cured, may be a laminate film laminated onto the carrier substrate 136, or the like. The top surface of the release layer 134 may be leveled and may have a high degree of planarity.

In FIG. 7, a thinning process of a back side of the substrate 217 is performed to expose the TSVs 211. The thinning process of the back side of the substrate 217 may be performed by a planarization process such as CMP, grinding, or etching. The thinning process may result in surfaces of the TSVs 211 being level with surfaces of the back side of the substrate 217.

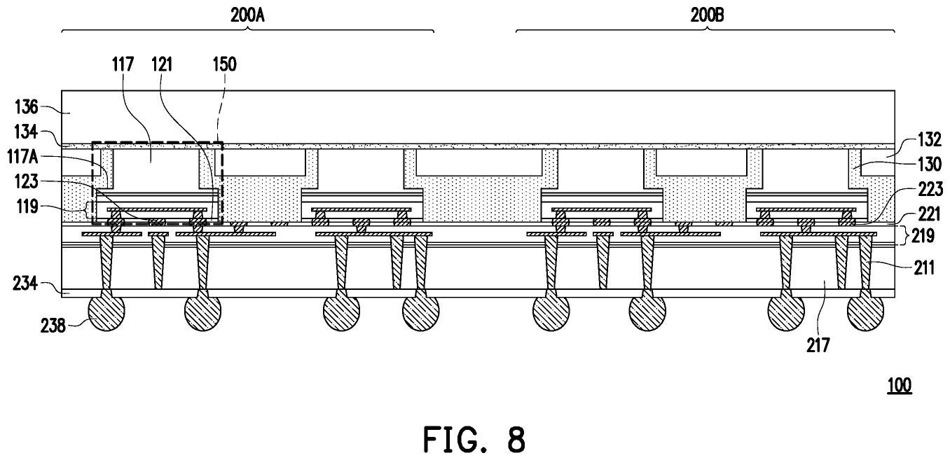

In FIG. 8, a polymer layer 234 is formed over the substrate 217 and the exposed surfaces of the TSVs 211. In an embodiment, the polymer layer 234 may comprise polybenzoxazole (PBO), a polymide (PI), a polymide derivative, or the like. The polymer layer 234 may be formed using a spin-coating process, or the like. FIG. 8 additionally illustrates a patterning of the polymer layer 234 in order to form openings that expose the TSVs 211. In an embodiment, the polymer layer 234 may be patterned using, e.g., a laser drilling method. In such a method a protective layer, such as a light-to-heat conversion (LTHC) layer (not separately illustrated in FIG. 8) is first deposited over the polymer layer 234. Once protected, a laser is directed towards those portions of the polymer layer 234 which are desired to be removed in order to expose the underlying TSVs 211.

In another embodiment, the polymer layer 234 may be patterned to form the openings that expose the TSVs 211 by initially applying a photoresist (not individually illustrated in FIG. 8) to the polymer layer 234 and then exposing the photoresist to a patterned energy source (e.g., a patterned light source) so as to induce a chemical reaction, thereby inducing a physical change in those portions of the photoresist exposed to the patterned light source. A developer is then applied to the exposed photoresist to take advantage of the physical changes and selectively remove either the exposed portion of the photoresist or the unexposed portion of the photoresist, depending upon the desired pattern, and the underlying exposed portion of the polymer layer 234 are removed with, e.g., a dry etch process. However, any other suitable method for patterning the polymer layer 234 to form the openings may be utilized.

Conductive connectors 238 are then formed over the polymer layer 234 and in the openings of the polymer layer 234. The conductive connectors 238 are electrically coupled to the semiconductor dies 150 through the TSVs 211. The conductive connectors 238 may comprise controlled collapse chip connection (C4) bumps, ball grid array (BGA) connectors, solder balls, or the like. The conductive connectors 238 may comprise a conductive material such as solder, copper, aluminum, gold, nickel, silver, palladium, tin, the like, or a combination thereof. In some embodiments, the conductive connectors 238 are formed by initially forming a layer of solder through evaporation, electroplating, printing, solder transfer, ball placement, or the like. Once a layer of solder has been formed on the structure, a reflow may be performed in order to shape the material into the desired bump shapes.

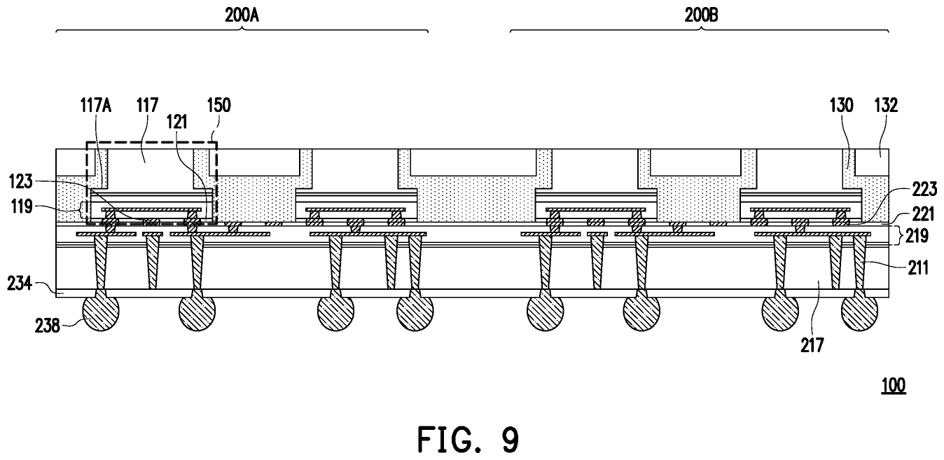

In FIG. 9, a de-bonding of the carrier substrate 136 is then performed to detach (or “de-bond”) the carrier substrate 136 from the semiconductor dies 150, the dielectric layer 130, and the molding material 132. In accordance with some embodiments, the de-bonding includes projecting a light such as a laser light or an UV light on the release layer 134 so that the release layer 134 decomposes under the heat of the light. The carrier substrate 136 can then be mechanically removed from the integrated chip package 100.

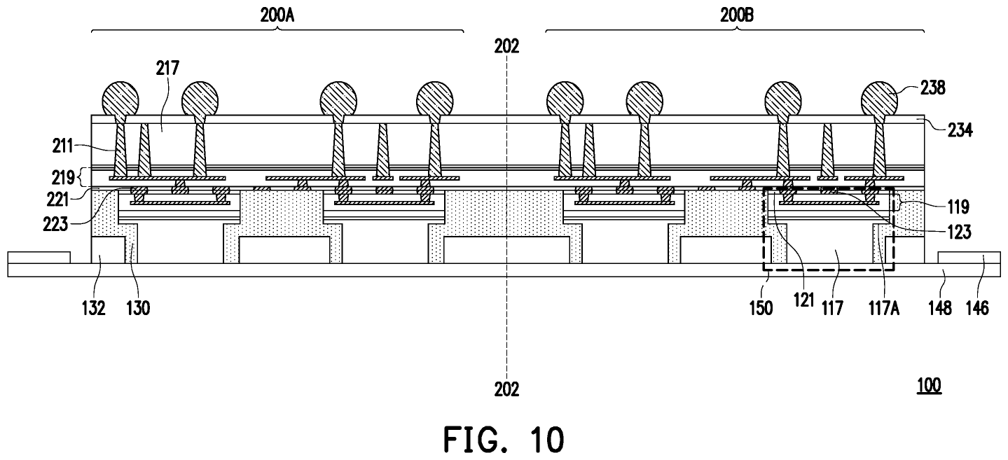

In FIG. 10, the structure of FIG. 9 is flipped over and attached to a tape 148 supported by a frame 146. The tape 148 may be a dicing tape for holding the integrated chip package 100 in place in subsequent processing.

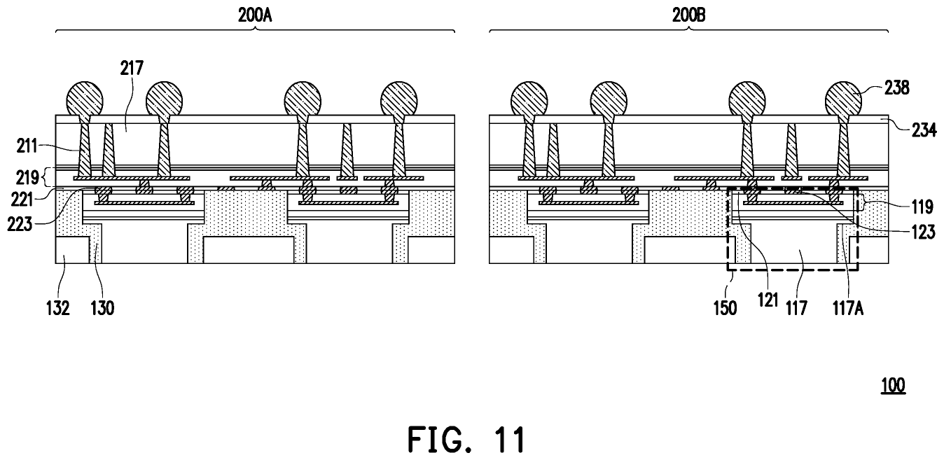

In FIG. 11, a singulation process is performed to singulate the first package region 200A from the second package region 200B along a dicing path 202 (shown previously in FIG. 10) or a scribe line region. The singulation process may comprise a laser grooving process, during which a laser beam is used to ablate portions of the polymer layer 234, the substrate 217, the interconnect structure 219, and the bonding layer 221 that are disposed along the dicing path 202 to form a groove that extends through the polymer layer 234, the substrate 217, the interconnect structure 219, and the bonding layer 221. After the laser grooving process, a sawing process is then performed along the remainder of the dicing path 202 to complete the singulation of the first package region 200A from the second package region 200B. Each of the resulting, singulated device stacks are from one of the first package region 200A or the second package region 200B.

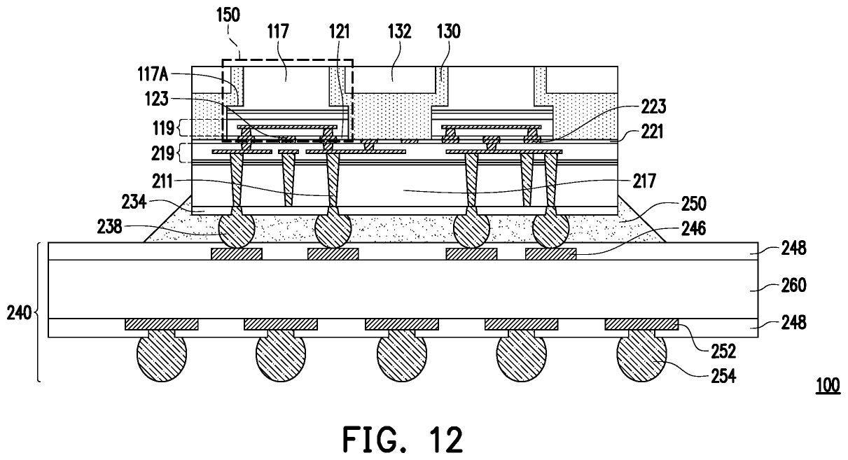

In FIG. 12, a package substrate 240 is coupled to the singulated device stack from one of the first package region 200A or the second package region 200B that was shown previously in FIG. 11. The package substrate 240 may comprise an interposer, a package, a core substrate, a coreless substrate, a printed circuit board (PCB), or the like. In an embodiment, the package substrate 240 includes a substrate core 260 and bond pads 246 over the substrate core 260. The substrate core 260 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 260 may be an SOI substrate. Generally, an SOI substrate includes a layer of a semiconductor material such as epitaxial silicon, germanium, silicon germanium, SOI, SGOI, or combinations thereof. The substrate core 260 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 260.

The substrate core 260 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 260 may also include metallization layers and vias (not shown), with the bond pads 246 being physically and/or electrically coupled to the metallization layers and vias. The metallization layers may be formed over the active and passive devices and are designed to connect the various devices to form functional circuitry. The metallization layers may be formed of alternating layers of dielectric material (e.g. low-k dielectric material) and conductive material (e.g., copper) with vias interconnecting the layers of conductive material and may be formed through any suitable process (such as deposition, damascene, dual damascene, or the like). In some embodiments, the substrate core 260 is substantially free of active and passive devices.

In some embodiments, the conductive connectors 238 are reflowed to attach the singulated device stack from one of the first package region 200A or the second package region 200B to the bond pads 246. The conductive connectors 238 electrically and/or physically couple the package substrate 240, including metallization layers in the substrate core 260, to the singulated device stack. In some embodiments, a solder resist 248 is formed on the substrate core 260. The conductive connectors 238 may be disposed in openings in the solder resist 248 to be electrically and mechanically coupled to the bond pads 246. The solder resist 248 may be used to protect areas of the substrate core 260 from external damage.

The conductive connectors 238 may have an epoxy flux (not shown) formed thereon before they are reflowed with at least some of the epoxy portion of the epoxy flux remaining after the singulated device stack is attached to the package substrate 240. This remaining epoxy portion may act as an underfill to reduce stress and protect the joints resulting from reflowing the conductive connectors 238. In some embodiments, an underfill 250 may be formed between the singulated device stack and the package substrate 240, and surrounding the conductive connectors 238. The underfill 250 may be formed by a capillary flow process after the coupling of the singulated device stack to the package substrate 240 or may be formed by a suitable deposition method before the package substrate 240 is coupled to the singulated device stack.

In an embodiment, the package substrate 240 may comprise bond pads 252 over the substrate core 260. Conductive connectors 254 may be coupled to the bond pads 252 to allow for the electrical coupling of the package substrate 240 to external circuits or devices. The conductive connectors 254 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 254 may include a conductive material such as solder, copper, aluminum, gold, nickel, silver, palladium, tin, the like, or a combination thereof. In some embodiments, the solder resist 248 is formed on the substrate core 260 and the conductive connectors 254 may be disposed in openings in the solder resist 248 to be electrically and mechanically coupled to the bond pads 252. The solder resist 248 may be used to protect areas of the substrate core 260 from external damage.

In some embodiments, passive devices (e.g., surface mount devices (SMDs), not shown) may also be attached to the package substrate 240 (e.g., to the bond pads 246). For example, the passive devices may be bonded to a same surface of the package substrate 240 as the conductive connectors 238.

The embodiments of the present disclosure have some advantageous features. The embodiments include a method for the formation of an integrated chip package. Forming the integrated chip package comprises bonding two or more semiconductor dies (e.g., top dies) to a semiconductor wafer (e.g., a bottom die). A dielectric layer (e.g., an oxide) is formed on top surfaces and sidewalls of the semiconductor dies, and on bottom surfaces of gaps between the semiconductor dies. A molding compound is then formed to fill the remainder of the gaps. As a result, the better bonding strength of the dielectric layer as compared to the molding compound allows for improved bonding of the semiconductor dies to the semiconductor wafer. In addition, the dielectric layer has a lower thermal expansion than the molding compound during a thermal process that is used to cure the molding compound. As a result, each semiconductor die has a better bending resistance at each die corner, and a risk of delamination of the semiconductor die is reduced. This further results in a more robust integrated chip package, with better electrical connection to any external devices (e.g., a package substrate), which allows for an enhancement in device reliability.

In accordance with an embodiment, a method of manufacturing a semiconductor device includes singulating a first wafer to separate a first die of the first wafer from a second die of the first wafer; bonding the first die and the second die to a first side of a second wafer, where after bonding the first die and the second die to the first side of the second wafer, a gap is disposed between the first die and the second die, where a first dielectric layer of each of the first die and the second die is directly bonded to a second dielectric layer of the second wafer, and where a first portion of the gap has a first width that is larger than a second width of a second portion of the gap; depositing a third dielectric layer on top surfaces and sidewalls of the first die and the second die, as well as on a bottom surface within the gap; forming a molding material over the third dielectric layer to fill the gap; performing a planarization process to expose top surfaces of the first die and the second die; and coupling a package substrate to a second side of the second wafer using conductive connectors, the second side of the second wafer being an opposite side of the second wafer as the first side of the second wafer. In an embodiment, the third dielectric layer includes silicon oxide, silicon oxynitride, silicon carbon nitride or tetraethyl orthosilicate. In an embodiment, a thickness of the third dielectric layer is in a range from 0.1 μm to 2 μm. In an embodiment, a material of the third dielectric layer is different from a material of the first dielectric layer and the second dielectric layer. In an embodiment, performing the planarization process further includes removing a portion of the third dielectric layer and a portion of the molding material, where after performing the planarization process, the top surfaces of the first die and the second die are level with top surfaces of the third dielectric layer and the molding material. In an embodiment, the method further includes after performing the planarization process, attaching a carrier substrate to the top surfaces of the first die and the second die, and the planarized surfaces of the third dielectric layer and the molding material; and thinning a back side of a substrate of the second wafer to expose through substrate vias (TSVs) within the second wafer. In an embodiment, singulating the first wafer to separate the first die of the first wafer from the second die of the first wafer includes performing a plasma dicing process on a first side of the first wafer to form a first groove and a second groove that are disposed between adjacent sidewalls of the first die and the second die; and performing a blade dicing process on a second side of the first wafer to form a trench, where the trench overlaps and connects to the first groove and the second groove.

In accordance with an embodiment, a method of manufacturing a semiconductor device includes bonding a plurality of dies to a wafer, where after bonding the plurality of dies to the wafer, a gap is disposed between adjacent dies of the plurality of dies, where a top portion of the gap has a larger width than a width of a bottom portion of the gap; depositing a first dielectric layer on sidewalls of the adjacent dies within the gap, as well as on a bottom surface of the gap, where the first dielectric layer fills the bottom portion of the gap; forming a molding material to fill the top portion of the gap; and planarizing the molding material such that a top surface of the molding material is level with top surfaces of the adjacent dies of the plurality of dies. In an embodiment, the first dielectric layer isolates the molding material from the sidewalls of the adjacent dies, and from a top surface of the wafer within the gap. In an embodiment, a thickness of the first dielectric layer is in a range from 0.1 μm to 2 μm. In an embodiment, the method further includes planarizing the first dielectric layer such that a top surface of the first dielectric layer is level with the top surface of the molding material and the top surfaces of the adjacent dies of the plurality of dies. In an embodiment, each of the plurality of dies includes a top portion having a first width; and a bottom portion having a second width, the second width being larger than the first width. In an embodiment, after planarizing the molding material, the first dielectric layer is in physical contact with top surfaces of the bottom portion of each of the plurality of dies. In an embodiment, the first dielectric layer includes an oxide.

In accordance with an embodiment, a package includes a first die and a second die over and bonded to a first side of a third die, where the first die and the second die include top portions; and bottom portions, where each top portion has a first width, and each bottom portion has a second width that is larger than the first width; a first dielectric layer disposed on adjacent sidewalls of the top portions and on adjacent sidewalls of the bottom portions; and a molding material over the first dielectric layer, where the molding material is disposed above the bottom portions of the first die and the second die, and where a top surface of the molding material is level with a top surface of the first dielectric layer. In an embodiment, a thickness of the first dielectric layer is in a range from 0.1 μm to 2 μm. In an embodiment, the first dielectric layer isolates the molding material from the first die and the second die. In an embodiment, a co-efficient of thermal expansion of the first dielectric layer is lower than a co-efficient of thermal expansion of the molding material. In an embodiment, the first dielectric layer is in physical contact with top surfaces of the bottom portions of the first die and the second die. In an embodiment, the package further includes a package substrate coupled to a second side of the third die using conductive connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
singulating a first wafer to separate a first die of the first wafer from a second die of the first wafer;
bonding the first die and the second die to a first side of a second wafer, wherein after bonding the first die and the second die to the first side of the second wafer, a gap is disposed between the first die and the second die, wherein a first dielectric layer of each of the first die and the second die is directly bonded to a second dielectric layer of the second wafer, and wherein a first portion of the gap has a first width that is larger than a second width of a second portion of the gap;
depositing a third dielectric layer on top surfaces and sidewalls of the first die and the second die, as well as on a bottom surface within the gap;
forming a molding material over the third dielectric layer to fill the gap;
performing a planarization process to expose top surfaces of the first die and the second die; and
coupling a package substrate to a second side of the second wafer using conductive connectors, the second side of the second wafer being an opposite side of the second wafer as the first side of the second wafer.

2. The method of claim 1, wherein the third dielectric layer comprises silicon oxide, silicon oxynitride, silicon carbon nitride or tetraethyl orthosilicate.

3. The method of claim 2, wherein a thickness of the third dielectric layer is in a range from 0.1 μm to 2 μm.

4. The method of claim 2, wherein a material of the third dielectric layer is different from a material of the first dielectric layer and the second dielectric layer.

5. The method of claim 1, wherein performing the planarization process further comprises removing a portion of the third dielectric layer and a portion of the molding material, wherein after performing the planarization process, the top surfaces of the first die and the second die are level with top surfaces of the third dielectric layer and the molding material.

6. The method of claim 5, further comprising:
after performing the planarization process, attaching a carrier substrate to the top surfaces of the first die and the second die, and the planarized surfaces of the third dielectric layer and the molding material; and
thinning a back side of a substrate of the second wafer to expose through substrate vias (TSVs) within the second wafer.

7. The method of claim 1, wherein singulating the first wafer to separate the first die of the first wafer from the second die of the first wafer comprises:
performing a plasma dicing process on a first side of the first wafer to form a first groove and a second groove that are disposed between adjacent sidewalls of the first die and the second die; and
performing a blade dicing process on a second side of the first wafer to form a trench, wherein the trench overlaps and connects to the first groove and the second groove.

8. A method of manufacturing a semiconductor device, the method comprising:
bonding a plurality of dies to a wafer, wherein after bonding the plurality of dies to the wafer, a gap is disposed between adjacent dies of the plurality of dies, wherein a top portion of the gap has a larger width than a width of a bottom portion of the gap;
depositing a first dielectric layer on sidewalls of the adjacent dies within the gap, as well as on a bottom surface of the gap, wherein the first dielectric layer fills the bottom portion of the gap;
forming a molding material to fill the top portion of the gap; and
planarizing the molding material such that a top surface of the molding material is level with top surfaces of the adjacent dies of the plurality of dies.

9. The method of claim 8, wherein the first dielectric layer isolates the molding material from the sidewalls of the adjacent dies, and from a top surface of the wafer within the gap.

10. The method of claim 9, wherein a thickness of the first dielectric layer is in a range from 0.1 μm to 2 μm.

11. The method of claim 8, further comprising:
planarizing the first dielectric layer such that a top surface of the first dielectric layer is level with the top surface of the molding material and the top surfaces of the adjacent dies of the plurality of dies.

12. The method of claim 8, wherein each of the plurality of dies comprises:
a top portion having a first width; and
a bottom portion having a second width, the second width being larger than the first width.

13. The method of claim 12, wherein after planarizing the molding material, the first dielectric layer is in physical contact with top surfaces of the bottom portion of each of the plurality of dies.

14. The method of claim 8, wherein the first dielectric layer comprises an oxide.

15. A package comprising:
a first die and a second die over and bonded to a first side of a third die, wherein the first die and the second die comprise:
top portions; and
bottom portions, wherein each top portion has a first width, and each bottom portion has a second width that is larger than the first width;
a first dielectric layer disposed on adjacent sidewalls of the top portions and on adjacent sidewalls of the bottom portions; and
a molding material over the first dielectric layer, wherein the molding material is disposed above the bottom portions of the first die and the second die, and wherein a top surface of the molding material is level with a top surface of the first dielectric layer.

16. The package of claim 15, wherein a thickness of the first dielectric layer is in a range from 0.1 μm to 2 μm.

17. The package of claim 15, wherein the first dielectric layer isolates the molding material from the first die and the second die.

18. The package of claim 15, wherein a co-efficient of thermal expansion of the first dielectric layer is lower than a co-efficient of thermal expansion of the molding material.

19. The package of claim 15, wherein the first dielectric layer is in physical contact with top surfaces of the bottom portions of the first die and the second die.

20. The package of claim 15 further comprising:
a package substrate coupled to a second side of the third die using conductive connectors.
